(19) United States
(12) Patent Application Publication
(10) Pub. No.: US 2025/0160219 A1
(43) Pub. Date: May 15, 2025

(54) PAD OVER ACTIVE SENSOR CELLS INTEGRATED IN A CHIP PACKAGE

(71) Applicant: Infineon Technologies AG, Neubiberg (DE)

(72) Inventors: Walter HARTNER, Bad Abbach (DE); Fabian MUTZBAUER, Burglengenfeld (DE)

(21) Appl. No.: 18/505,701

(22) Filed: Nov. 9, 2023

(51) Int. Cl. H10N 59/00; G01R 33/00; G01R 33/09; H01L 23/00

(52) U.S. Cl. CPC H10N 59/00; G01R 33/0047; G01R 33/0052; G01R 33/093; G01R 33/098; H01L 24/05; H01L 2224/05022; H01L 2224/05073; H01L 2224/05124; H01L 2224/05147; H01L 2224/05562; H01L 2224/05568; H01L 2224/05572; H01L 2224/05573; H01L 2224/05644; H01L 2224/05655; H01L 2224/05664; H01L 2924/0134

(57) ABSTRACT

A chip-scale package includes a magnetic sensor integrated circuit (IC) and a conductive contact pad. The magnetic sensor IC includes an IC layer stack comprising a plurality of isolation layers and a plurality of conductive layers; and a magnetoresistive sensing element integrated in the IC layer stack. The magnetoresistive sensing element includes a reference layer having a fixed reference magnetization aligned with a magnetization axis, and a magnetic free layer having a magnetically free magnetization. The magnetically free magnetization is variable in a presence of an external magnetic field. The conductive contact pad is arranged on or integrated in the IC layer stack. Moreover, the conductive contact pad is arranged over the magnetoresistive sensing element such that the conductive contact pad and the magnetoresistive sensing element at least partially vertically overlap.

### BACKGROUND

Magnetic field sensors based on a magnetoresistance effect are referred to as magnetoresistive sensors and are often used in magnetic field sensing applications, such as current sensing, position sensing, and angle sensing. Magnetoresistance is a property of a material to change a value of the material's electrical resistance when an external magnetic field is applied to the material. On account of magnetoresistive sensors' high signal level and high accuracy, and the possibility to integrate magnetoresistive sensors into complementary metal-oxide-semiconductor (CMOS) and bipolar-CMOS (BiCMOS) technologies, magnetoresistive sensors may be a preferred choice over Hall-based sensors. Some types of magnetoresistive sensors include anisotropic magnetoresistance (AMR) sensors, giant magnetoresistance (GMR) sensors, and tunnel magnetoresistance (TMR) sensors, each of which utilizes a corresponding magnetoresistive effect.

The large number of different magnetoresistive effects is often abbreviated to xMR, where the “x” serves as a placeholder for the different magnetoresistive effects. xMR sensors can detect the orientation of an applied magnetic field by measuring sine and cosine angle components using monolithically integrated magnetoresistive sensing elements. Here, the acronym respectively of the xMR sensor denotes the magnetoresistive effect used for measuring a respective magnetic field. In this regard, a GMR effect is a quantum mechanical magnetoresistance effect that is observed in thin-film structures comprising alternating ferromagnetic and non-magnetic conductive layers. A TMR effect occurs in a magnetic tunnel junction (MTJ), wherein the magnetic tunnel junction occurs at a thin insulator that separates two ferromagnets from one another. An AMR effect is a property of a material in which a dependence of the electrical resistance on an angle between a direction of an electric current (e.g., a sensing axis) and a magnetization direction is observed. The magnetoresistive effect may be related to a sensitivity of an xMR sensor. For example, the magnetoresistive effect may be increased in order to increase the sensitivity of the xMR sensor.

### SUMMARY

In some implementations, a chip-scale package includes a magnetic sensor integrated circuit (IC) comprising: an IC layer stack comprising a plurality of isolation layers and a plurality of conductive layers; and a magnetoresistive sensing element integrated in the IC layer stack, wherein the magnetoresistive sensing element includes a reference layer having a fixed reference magnetization aligned with a magnetization axis, and a magnetic free layer having a magnetically free magnetization, and wherein the magnetically free magnetization is variable in a presence of an external magnetic field; and a conductive contact pad arranged on or integrated in the IC layer stack, wherein the conductive contact pad is arranged over the magnetoresistive sensing element such that the conductive contact pad and the magnetoresistive sensing element at least partially vertically overlap.

In some implementations, a chip-scale package includes a magnetic sensor IC comprising: an IC layer stack comprising a plurality of isolation layers and a plurality of conductive layers; and a plurality of magnetoresistive sensing elements integrated in the IC layer stack, including a first plurality of magnetoresistive sensing elements arranged in a first sensor area and a second plurality of magnetoresistive sensing elements arranged in a second sensor area, wherein the first sensor area and the second sensor area are laterally separated; a first conductive contact pad arranged on or integrated in the IC layer stack, wherein the first conductive contact pad is arranged over the first sensor area such that the first conductive contact pad and the first sensor area at least partially vertically overlap; and a second conductive contact pad arranged on or integrated in the IC layer stack, wherein the second conductive contact pad is arranged over the second sensor area such that the second conductive contact pad and the second sensor area at least partially vertically overlap.

In some implementations, a method of manufacturing a chip-scale package includes providing a substrate; forming a magnetic sensor IC on the substrate, wherein the magnetic sensor IC includes: an IC layer stack comprising a plurality of isolation layers and a plurality of conductive layers, and a plurality of magnetoresistive sensing elements integrated in a sensor area of the IC layer stack; and forming a conductive contact pad on or integrated at a top of the IC layer stack, wherein the conductive contact pad is arranged over the plurality of magnetoresistive sensing elements such that the conductive contact pad and the plurality of magnetoresistive sensing elements at least partially vertically overlap.

### BRIEF DESCRIPTION OF THE DRAWINGS

Implementations are described herein with reference to the appended drawings.

FIG. 1 shows an example of a layer stack of a magnetoresistive sensing element according to one or more implementations.

FIG. 2 shows a cross-section of a chip-scale package according to one or more implementations.

FIG. 3 shows a cross-section of a chip-scale package according to one or more implementations.

FIG. 4 shows a cross-section of a chip-scale package according to one or more implementations.

FIG. 5 is a flowchart of an example process associated with forming a pad over active sensor cells integrated in a chip package.

### DETAILED DESCRIPTION

In the following, details are set forth to provide a more thorough explanation of example implementations. However, it will be apparent to those skilled in the art that these implementations may be practiced without these specific details. In other instances, well-known structures and devices are shown in block diagram form or in a schematic view, rather than in detail, in order to avoid obscuring the implementations. In addition, features of the different implementations described hereinafter may be combined with each other, unless specifically noted otherwise.

Further, equivalent or like elements or elements with equivalent or like functionality are denoted in the following description with equivalent or like reference numerals. As the same or functionally equivalent elements are given the same reference numbers in the figures, a repeated description for elements provided with the same reference numbers may be omitted. Hence, descriptions provided for elements having the same or like reference numbers are mutually interchangeable.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “top,” “bottom,” “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

In implementations described herein or shown in the drawings, any direct electrical connection or coupling (e.g., any connection or coupling without additional intervening elements) may also be implemented by an indirect connection or coupling (e.g., a connection or coupling with one or more additional intervening elements, or vice versa) as long as the general purpose of the connection or coupling (e.g., to transmit a certain kind of signal or to transmit a certain kind of information) is essentially maintained. Features from different implementations may be combined to form further implementations. For example, variations or modifications described with respect to one of the implementations may also be applicable to other implementations unless noted to the contrary.

As used herein, the terms “substantially” and “approximately” mean “within reasonable tolerances of manufacturing and measurement.” For example, the terms “substantially” and “approximately” may be used herein to account for small manufacturing tolerances or other factors (e.g., within 5%) that are deemed acceptable in the industry without departing from the aspects of the implementations described herein. For example, a resistor with an approximate resistance value may practically have a resistance within 5% of the approximate resistance value. As another example, a signal with an approximate signal value may practically have a signal value within 5% of the approximate signal value.

In the present disclosure, expressions including ordinal numbers, such as “first”, “second”, and/or the like, may modify various elements. However, such elements are not limited by such expressions. For example, such expressions do not limit the sequence and/or importance of the elements. Instead, such expressions are used merely for the purpose of distinguishing an element from the other elements. For example, a first box and a second box indicate different boxes, although both are boxes. For further example, a first element could be termed a second element, and similarly, a second element could also be termed a first element without departing from the scope of the present disclosure.

“Sensor” may refer to a component which converts a property to be measured to an electric signal (e.g., a current signal or a voltage signal). The property to be measured may, for example, comprise a magnetic field, an electric field, an electromagnetic wave (e.g., a radio wave), a pressure, a force, a current, or a voltage, but is not limited thereto. For instance, there are various sensor techniques for measuring a current flowing through a conductor or a position of an object in connection with a magnetic field.

A wire bond package has been used as a package for a magnetic sensor integrated circuit (IC) (e.g., sensor die). However, any contact pad for making a wire bond connection needs to be laterally offset from any magnetic sensing elements (e.g., sensor cells) that are integrated in the magnetic sensor IC, due to a force exerted onto the wire bond package during wire bonding. Otherwise, part of the force may be imparted onto the magnetic sensing elements and damage the magnetic sensing elements. In other words, if the wire bond connection were to be arranged directly over (e.g., vertically over) the magnetic sensing elements, the magnetic sensing elements may be damaged as a result of the force applied to the contact pad during a wire bonding process. However, a size of the magnetic sensor IC (e.g., a size of the sensor die) needs to be increased in order to provide a sufficient lateral offset between the contact pad and the magnetic sensing elements. Larger die sizes are typically associated with higher manufacturing costs and/or system costs.

Thus, an area of the magnetic sensor IC located above the magnetic sensing elements (e.g., an active sensor area) is not accessible for the contact pad. Instead, the contact pad is placed laterally offset from the magnetic sensing elements. Moreover, a metal layer of the contact pad is processed before the magnetic sensing elements are integrated within the magnetic sensor IC (e.g., before forming the magnetic sensing elements). After completing the process steps for forming the magnetic sensing elements, an area above the contact pad is opened for wire bonding. Accordingly, a manufacturing process is complicated with additional process steps that include forming the contact pad within the magnetic sensor IC, covering the contact pad with additional process layers, forming the magnetic sensing elements after the contact pad is formed and covered, and, after forming the magnetic sensing elements, removing the additional process layers above the contact pad to expose the contact pad for wire bonding.

Accordingly, some implementations disclosed herein are directed to a chip-scale package that includes a magnetic sensor IC and a conductive contact pad. The magnetic sensor IC may be a sensor die. The magnetic sensor IC includes an IC layer stack comprising a plurality of isolation layers and a plurality of conductive layers, and a magnetoresistive sensing element integrated in the IC layer stack. The magnetoresistive sensing element includes a reference layer having a fixed reference magnetization aligned with a magnetization axis, and a magnetic free layer having a magnetically free magnetization. The magnetically free magnetization is variable in a presence of an external magnetic field. The conductive contact pad is arranged on or integrated in the IC layer stack. Moreover, the conductive contact pad is arranged over the magnetoresistive sensing element such that the conductive contact pad and the magnetoresistive sensing element at least partially vertically overlap. As a result, a size of the magnetic sensor IC (e.g., a die size), particularly in a lateral dimension, may be decreased. In other words, a lateral area of the magnetic sensor IC may be smaller than a lateral area of a magnetic sensor IC that requires a lateral offset between the conductive contact pad and the magnetoresistive sensing element.

The chip-scale package may be a single-die, direct-surface mountable package. In some implementations, the chip-scale package may be a wafer-level chip-scale package (WLCSP), which includes the single die packaged at the wafer level. A WLCSP may have a same size as the single die. In some implementations, the chip-scale package may not use any bond wires for electrical connection between components. In other words, the chip-scale package may be completely devoid of wire bonds. Instead, a conductive contact pad and/or a solder pad may be used for making electrical connections with the chip-scale package. Additionally, conductive layers, conductive vias, and/or conductive pillars may be used for making electrical connections to the single die and/or to integrate components within the single die.

In some implementations, the conductive contact pad is a last metal layer of the IC layer stack. In other words, the conductive contact pad is formed after the magnetoresistive sensing element is formed in the magnetic sensor IC and the conductive contact pad is an uppermost conductive layer of the IC layer stack. Thus, additional IC layers are not formed on top of the conductive contact pad, which eliminates a removal process step that would otherwise be needed to remove additional process layers above the conductive contact pad for exposing the conductive contact pad for electrical contact.

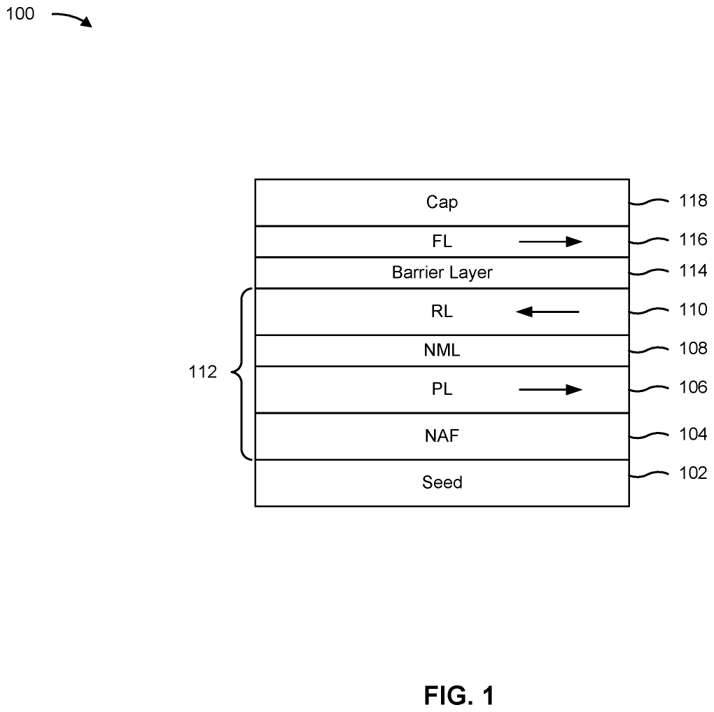

FIG. 1 shows an example of a layer stack of a magnetoresistive sensing element 100 according to one or more implementations. For example, the magnetoresistive sensing element 100 may be a TMR sensing element with a bottom-pinned spin-valve (BSV) configuration. Additionally, the magnetoresistive sensing element 100 can be arranged on a semiconductor substrate (not shown) of a magnetoresistive sensor. If described in a Cartesian coordinate system with pair-wise perpendicular coordinate axes x, y, and z, layers of the layer stack extend laterally in a plane spanned by the x and y axes. Thus, lateral dimensions (e.g., lateral distances, lateral cross-sectional areas, lateral areas, lateral extensions, lateral displacements, etc.) may refer to dimensions in the xy-plane and vertical dimensions may refer to dimensions in a z-direction, perpendicular to the xy-plane. For example, a vertical extent of a layer in the z-direction may be described as a layer thickness.

The layer stack of the magnetoresistive sensing element 100 includes at least one reference layer with a reference magnetization (e.g., a reference direction in the case of GMR or TMR technology). The reference magnetization is a magnetization direction that provides a sensing direction corresponding to a sensing axis of the magnetoresistive sensing element 100. The reference layer, and consequently the reference magnetization, defines a sensor plane. For example, the sensor plane may be defined by the xy-plane. Thus, the x-direction and the y-direction may be referred to as “in-plane” with respect to the sensor plane and the z-direction may be referred to as “out-of-plane” with respect to the sensor plane.

Accordingly, in the case of a GMR sensing element or a TMR sensing element, if a magnetically free magnetization of a magnetic free layer points exactly in a same direction as the reference magnetization (e.g., the reference direction), a resistance of the magnetoresistive sensing element 100 is at a minimum and, if the magnetically free magnetization of the magnetic free layer points exactly in an opposite direction as the reference magnetization, the resistance of the magnetoresistive sensing element 100 is at a maximum. An orientation of the magnetically free magnetization of the magnetic free layer is variable in a presence of an external magnetic field. Thus, the resistance of the magnetoresistive sensing element 100 can vary based on an influence of the external magnetic field on the magnetically free magnetization of the magnetic free layer.

From the bottom up, the magnetoresistive sensing element 100 may comprise an optional seed layer 102 that may be used to influence and/or optimize a stack growth. In some implementations, the seed layer 102 may be copper, tantalum, ruthenium, or a combination thereof. A natural antiferromagnetic (NAF) layer 104 is formed or otherwise disposed on the seed layer 102. The NAF layer 104 may be made of platinum-manganese (PtMn), iridium-manganese (IrMn), nickel-manganese (NiMn), or the like. A film thickness of the NAF can be in the range of 5 nm to 50 nm.

In addition, a pinned layer (PL) 106 may be formed or otherwise disposed on the NAF layer 104. The pinned layer 106 may be made of a ferromagnetic material, such as cobalt-iron (CoFe) or cobalt-iron-boron (CoFeB). Contact between the NAF layer 104 and the pinned layer 106 can provoke an effect known as an exchange bias effect, causing a magnetization of the pinned layer 106 to align in a preferred direction (e.g., in the x-direction, as shown). The magnetization of the pinned layer 106 may be referred to as a pinned magnetization. The pinned layer 106 can comprise a closed flux magnetization pattern in the xy-plane. This closed flux magnetization pattern of the pinned layer 106 may be generated during manufacturing of the magnetoresistive sensing element 100 and may be permanently fixed. Alternatively, the pinned layer 106 can comprise a linear magnetization pattern in the xy-plane (e.g., a homogenous orientation in one direction) that is permanently fixed.

The magnetoresistive sensing element 100 further comprises a non-magnetic layer (NML) referred to as coupling interlayer 108. The coupling interlayer 108 may be diamagnetic and may comprise ruthenium, iridium, copper, copper alloys, or similar materials, for example. A magnetic (e.g., ferromagnetic) reference layer (RL) 110 may be formed or otherwise disposed on the coupling interlayer 108. Thicknesses of the pinned layer 106 and the magnetic reference layer 110, respectively, may be in the range of 1 nm to 10 nm.

Accordingly, the coupling interlayer 108 may be arranged between the pinned layer 106 and the magnetic reference layer 110 in order to spatially separate the pinned layer 106 and the magnetic reference layer 110 in the vertical direction. In addition, the coupling interlayer 108 may provide an interlayer exchange coupling (e.g., an antiferromagnetic Ruderman-Kittel-Kasuya-Yosida (RKKY) coupling) between the pinned layer 106 and the magnetic reference layer 110 to form an artificial antiferromagnet. As a result, a magnetization of the magnetic reference layer 110 may align and be held in a direction anti-parallel or opposite to the magnetization of the pinned layer 106 (e.g., in the −x-direction, as shown). The magnetization of the magnetic reference layer 110 may be referred to as a reference magnetization.

Since the NAF layer 104 is configured to cause the magnetization of the pinned layer 106 to align and be fixed in a certain direction, and the coupling interlayer 108 is configured to cause the magnetization of the magnetic reference layer 110 to align and be fixed in an opposite direction, it can be said that the NAF layer 104 is configured to hold the magnetization of the pinned layer 106 (e.g., a fixed pinned magnetization) in a first magnetic orientation and hold the magnetization of the magnetic reference layer 110 (e.g., a fixed reference magnetization) in a second magnetic orientation. For example, if the pinned layer 106 comprises a clockwise closed flux magnetization pattern in the xy-plane, the magnetic reference layer 110 may comprise a counterclockwise closed flux magnetization pattern in the xy-plane (or vice versa). In this way, the magnetic reference layer 110 can have a permanent closed flux magnetization pattern. Moreover, in case the pinned layer 106 comprises a linear magnetization pattern in the xy-plane in a certain direction, the magnetic reference layer 110 may comprise a linear magnetization pattern in an anti-parallel direction. Thus, the NAF layer 104, the pinned layer 106, the coupling interlayer 108, and the magnetic reference layer 110 form a magnetic reference layer system 112 of the magnetoresistive sensing element 100.

The magnetoresistive sensing element 100 additionally comprises a barrier layer 114 (e.g., a tunnel barrier layer) arranged vertically between the reference layer system 112 and a magnetic free layer 116. For example, the barrier layer 114 may be formed or otherwise disposed on the magnetic reference layer 110 of the reference layer system 112, and the magnetic free layer 116 may be formed or otherwise disposed on the barrier layer 114.

The barrier layer 114 may be composed of a non-magnetic material. In some implementations, the barrier layer 114 may be an electrically insulating tunnel barrier layer. For example, the barrier layer 114 may be a tunnel barrier layer used for producing a TMR effect. The barrier layer 114 may comprise magnesium oxide (MgO) or another material with similar properties.

A material of the magnetic free layer 116 can be an alloy of a ferromagnetic material, such as CoFe, CoFeB, or NiFe. The magnetic free layer 116 has a magnetically free magnetization that is variable in a presence of an external magnetic field. Therefore, the magnetic free layer 116 may be referred to as a sensor layer, since changes in the magnetically free magnetization are used to determine a measured variable. In addition, the magnetically free magnetization has a default magnetic orientation in a ground state. The ground state is a state in which an influence of the external magnetic field on the magnetic free layer 116 is absent or negligibly small. In some implementations, the magnetoresistive sensing element 100 may include a magnetically free system that includes a plurality of layers (e.g., two or more magnetic free layers), which act in combination as the magnetically free layer. In this case, the magnetically free layers of the magnetically free system are magnetically coupled to each other. Thus, the magnetically free system can act as the magnetically free layer, but may comprise a plurality of layers. The magnetically free system has a magnetically free magnetization, wherein the magnetically free magnetization is variable in the presence of the external magnetic field.

A cap layer 118 made of, for example, tantalum (Ta), tantalum-nitride (TaN), ruthenium (Ru), titanium (Ti), titanium nitride (TiN), platinum (Pt), or the like, may be formed or otherwise disposed on the magnetic free layer 116 to form an upper layer of the magnetoresistive sensing element 100.

The seed layer 102 may serve as a bottom electrode or may provide electrical contact with a bottom electrode (not shown) of the magnetoresistive sensing element 100. The cap layer 118 may provide electrical contact with a top electrode (not shown) of the magnetoresistive sensing element 100. The barrier layer 114 may be designed to permit electrons to tunnel between the reference layer system 112 and the magnetic free layer 116 when a bias voltage is applied to electrodes of the magnetoresistive sensing element 100 (not shown) in order to provide a magnetoresistance effect (e.g., a TMR effect).

As indicated above, FIG. 1 is provided merely as an example. Other examples may differ from what is described with regard to FIG. 1. The number and arrangement of components shown in FIG. 1 are provided as an example. In practice, the magnetoresistive sensing element 100 may include additional elements, fewer elements, different elements, or differently arranged elements than those shown in FIG. 1.

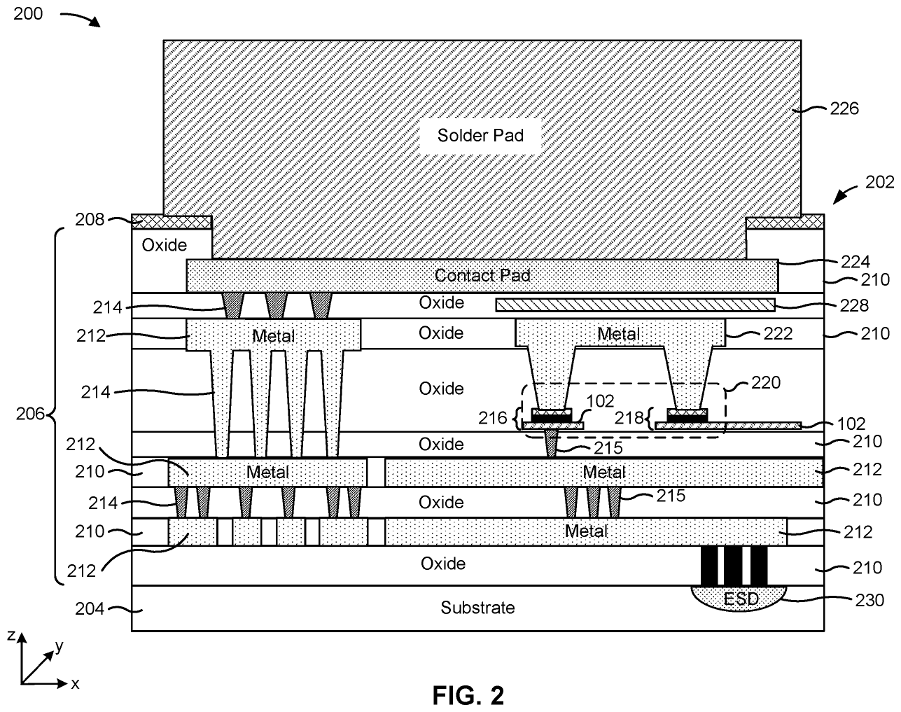

FIG. 2 shows a cross-section of a chip-scale package 200 according to one or more implementations. The chip-scale package 200 may include a magnetic sensor IC 202 (e.g., a semiconductor die) that includes a substrate 204, an IC layer stack 206, and a passivation layer 208. The substrate 204 may be a semiconductor substrate, such as a p-doped substrate. The IC layer stack 206 may be formed on the substrate 204. The IC layer stack 206 may include a plurality of isolation layers 210 (e.g., oxide layers) and a plurality of conductive layers 212 (e.g., metal layers). The plurality of conductive layers 212 may be made of aluminum (Al), copper (Cu), or another conductive material. The conductive layers 212 may be electrically connected by a first plurality of conductive vias 214 and a second plurality of conductive vias 215. The first plurality of conductive vias 214 and the second plurality of conductive vias 215 may be made of aluminum, copper, tungsten (W), or another conductive material. The first plurality of conductive vias 214 and the second plurality of conductive vias 215 may extend vertically into the IC layer stack, for example, in the z-direction. Thus, the first plurality of conductive vias 214 and the second plurality of conductive vias 215 may extend vertically through one or more isolation layers 210 in order to electrically couple two conductive layers 212. A pattern of various electrical connections may be formed between the conductive layers 212 using the conductive vias 214 and 215. In some implementations, the conductive vias 214 and/or conductive vias 215 may include conductive plugs, which may be considered a type of conductive via. The passivation layer 208 (e.g., silicon nitride (SiN)) may be formed on top of the IC layer stack 206.

The magnetic sensor IC 202 may further include magnetoresistive sensing elements 216 and 218 integrated in the IC layer stack 206. For example, the magnetoresistive sensing elements 216 and 218 may be TMR sensing elements, as similarly described in connection with FIG. 1. The magnetoresistive sensing elements 216 and 218 may be arranged in a sensor area 220 (e.g., an active sensor region) of the magnetic sensor IC 202. The magnetoresistive sensing elements 216 and 218 may be electrically coupled by a top electrode 222 that is formed by one of the conductive layers 212. The seed layer 102 of each of the magnetoresistive sensing elements 216 and 218 may be used as a bottom electrode (e.g., a supply contact). Each bottom electrode may be coupled to a respective conductive layer 212. A current may flow into the bottom electrode of the magnetoresistive sensor element 216 from one of the conductive layers 212, through the magnetoresistive sensor element 216 to the top electrode 222, from the top electrode 222 to the magnetoresistive sensor element 218, and through the magnetoresistive sensor element 218 to the bottom electrode of the magnetoresistive sensor element 218. Thus, the magnetoresistive sensing elements 216 and 218 may be arranged on a same current path.

The chip-scale package 200 may further include a conductive contact pad 224 arranged on or integrated in the IC layer stack 206. The conductive contact pad 224 may be an uppermost conductive layer of the IC layer stack 206. For example, the conductive contact pad 224 may be a last metal layer of the IC layer stack 206. The last metal layer may be a last conductive layer among all conductive layers 212 formed in the IC layer stack 206. Thus, the conductive contact pad 224 may be formed after integrating or forming the magnetoresistive sensing elements 216 and 218 in the IC layer stack 206. In some implementations, the conductive contact pad 224 may be formed on top of an uppermost isolation layer of the IC layer stack 206. For example, the conductive contact pad 224 may be coplanar with the passivation layer 208.

The conductive contact pad 224 may be made of aluminum, copper, or another conductive material. The conductive contact pad 224 may be arranged over the sensor area 220. In other words, the conductive contact pad 224 may be arranged over the magnetoresistive sensing elements 216 and 218 such that the conductive contact pad 224 and the magnetoresistive sensing elements 216 and 218 at least partially vertically overlap in, for example, the vertical direction (e.g., the z-direction). In some implementations, the conductive contact pad 224 may partially or fully overlap with the sensor area 220 in the vertical direction. For example, the conductive contact pad 224 may vertically overlap with the magnetoresistive sensing element 216 and/or the magnetoresistive sensing element 218.

The conductive contact pad 224 may be configured to supply the current to the magnetoresistive sensing elements 216 and 218. For example, the conductive contact pad 224 may be electrically coupled to the magnetoresistive sensing elements 216 and 218 by one or more conductive layers of the plurality of conductive layers 212. The first plurality of conductive vias 214 and the second plurality of conductive vias 215 may connect the conductive contact pad 224 to one or more conductive layers 212, and may be used to provide the current to the magnetoresistive sensing elements 216 and 218. The location of the first plurality of conductive vias 214 relative to the sensor area 220, with a lateral offset, may enable the conductive contact pad 224 to be arranged over the sensor area 220 while also enabling the current to be provided down into the IC layer stack 206 (e.g., to the bottom conductive layers). Thus, the conductive contact pad 224 may laterally extend over both the sensor area 220 and the first plurality of conductive vias 214.

At least one isolation layer 210 of the IC layer stack 206 may be arranged vertically between the conductive contact pad 224 and the magnetoresistive sensing elements 216 and 218. The first plurality of conductive vias 214 may be arranged laterally offset from the sensor area 220 (e.g., laterally offset from the magnetoresistive sensing elements 216 and 218), for example, in the x-direction. In contrast, the second plurality of conductive vias 215 may be arranged vertically underneath the sensor area 220. Thus, the current may flow from the conductive contact pad 224 down into the IC layer stack 206 by way of the first plurality of conductive vias 214, and may flow back up through the IC layer stack 206 to the magnetoresistive sensing elements 216 and 218 by way of the second plurality of conductive vias 215.

The chip-scale package 200 may further include a solder pad 226 arranged on the conductive contact pad 224. In some implementations, the solder pad 226 may be arranged directly on the conductive contact pad 224 (e.g., in direct contact with the conductive contact pad 224). Thus, the conductive contact pad 224 may be arranged vertically between the solder pad 226 and the sensor area 220 (e.g., vertically between the solder pad 226 and the magnetoresistive sensing elements 216 and 218). The solder pad 226 may be configured to supply or otherwise provide the current to the conductive contact pad 224 from a supply source. The solder pad 226 may be made of a nickel-phosphorus alloy, such as a nickel-phosphorus-palladium-gold alloy (NiP/Pd/Au), or another magnetic material. Thus, the solder pad 226 may be a magnetic metal layer arranged on top of the conductive contact pad 224 such that the magnetic metal layer and the sensor area 220 at least partially vertically overlap. In some implementations, the solder pad 226 may partially or fully overlap with the sensor area 220 in the vertical direction. For example, the solder pad 226 may vertically overlap with the magnetoresistive sensing element 216 and/or the magnetoresistive sensing element 218.

As a result of the current flowing through the solder pad 226, the solder pad 226 may produce a stray magnetic field. A shielding layer 228 may be provided between the solder pad 226 and the sensor area 220 in order to shield the magnetoresistive sensing elements 216 and 218 from the stray magnetic field produced by the solder pad 226. For example, the shielding layer 228 may be arranged in one of the isolation layers 210 that is provided between the conductive contact pad 224 and the top electrode 222.

In some implementations, the substrate 204 may include an electrostatic discharge region 230 for electrostatic discharge (ESD). The electrostatic discharge region 230 may be electrically coupled to one or more conductive layers 212 for dissipating electrostatic discharge that may accumulate in the IC layer stack 206.

By forming the conductive contact pad 224 over the sensor area 220 of the IC layer stack 206, a total lateral area in an xy-plane of the magnetic sensor IC 202 may be reduced. The chip-scale package 200 may be formed without any wire bonds. Moreover, by forming the conductive contact pad 224 as the uppermost conductive layer of the IC layer stack 206, a manufacturing process of the magnetic sensor IC 202 may be simplified, which may result in reduced manufacturing costs.

As indicated above, FIG. 2 is provided as an example. Other examples may differ from what is described with regard to FIG. 2. The number and arrangement of components shown in FIG. 2 are provided as an example. In practice, the chip-scale package 200 may include additional components, fewer components, different components, or differently arranged components than those shown in FIG. 2.

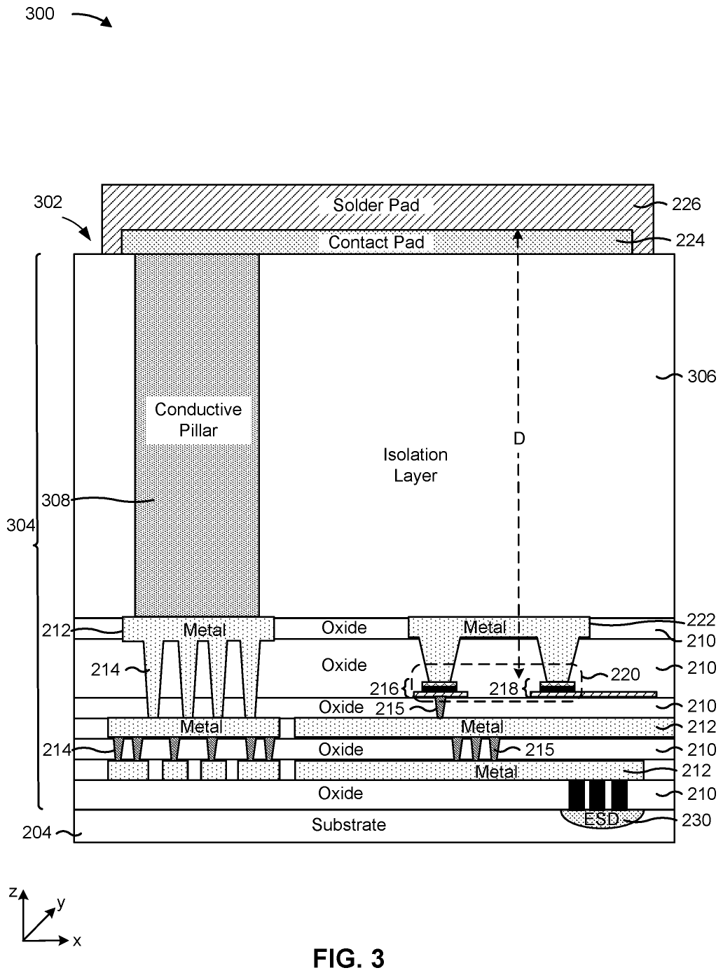

FIG. 3 shows a cross-section of a chip-scale package 300 according to one or more implementations. Some aspects of the chip-scale package 300 may be similar to the chip-scale package 200 described in connection with FIG. 2.

The chip-scale package 300 may include a magnetic sensor IC 302 (e.g., a semiconductor die) that includes the substrate 204 and an IC layer stack 304. The IC layer stack 304 may include the plurality of isolation layers 210, the plurality of conductive layers 212, the first plurality of conductive vias 214, the second plurality of conductive vias 215, and the magnetoresistive sensing elements 216 and 218, as similarly described in connection with FIG. 2. In addition, the IC layer stack 304 may include one or more isolation layers arranged vertically between the conductive contact pad 224 and the magnetoresistive sensing elements 216 and 218. In some implementations, the IC layer stack 304 may include a thick isolation layer 306 that is arranged vertically between the conductive contact pad 224 and the magnetoresistive sensing elements 216 and 218. The thick isolation layer 306 may be made of a dielectric material that provides electrical isolation. For example, the thick isolation layer 306 may be made of an oxide, an overmold material, or an imide. The conductive contact pad 224 may be arranged on (e.g., directly on) the thick isolation layer 306. In some implementations, the conductive contact pad 224 may be considered to be part of the IC layer stack 304 (e.g., the conductive contact pad 224 may be integrated in the IC layer stack 304). Alternatively, the conductive contact pad 224 may be considered to be arranged on the IC layer stack 304.

The solder pad 226 may be arranged directly on (e.g., in direct electrical contact with) the conductive contact pad 224. A thickness of the thick isolation layer 306 may be large enough to protect the magnetoresistive sensing elements 216 and 218 from any stray magnetic fields generated by the solder pad 226. For example, since a strength of a magnetic field decreases with distance from a magnetic field source, the thickness of the thick isolation layer 306 may be sufficiently large such that any stray magnetic field generated by the solder pad 226 is minimized at the magnetoresistive sensing elements 216 and 218. For example, the solder pad 226 and the magnetoresistive sensing elements 216 and 218 may be separated by a vertical distance D of at least 25 μm. In some implementations, the thickness of the thick isolation layer 306 may be at least 25 μm.

The conductive contact pad 224 may be electrically coupled to the magnetoresistive sensing elements 216 and 218 by one or more conductive layers of the plurality of conductive layers 212, and by the first plurality of conductive vias 214 and the second plurality of conductive vias 215. The first plurality of conductive vias 214 may be arranged laterally offset from the magnetoresistive sensing elements 216 and 218. In addition, the IC layer stack 304 may include a conductive pillar 308 coupled to the conductive contact pad 224 and to a conductive layer of the plurality of conductive layers 212. Thus, the conductive pillar 308 may connect the conductive contact pad 224 to the conductive layers 212. The conductive pillar 308 may be made of aluminum, copper, or another conductive material. The conductive pillar 308 may vertically extend through the thick isolation layer 306, between the conductive contact pad 224 and the conductive layer 212. In addition, the conductive pillar may be laterally offset from the magnetoresistive sensing elements 216 and 218, for example, in the x-direction.

Current provided by the solder pad 226 may flow from the conductive contact pad 224 through the conductive pillar 308, and through a network of conductive vias and conductive layers of the IC layer stack 304 to the magnetoresistive sensing elements 216 and 218. The location of the conductive pillar 308 relative to the sensor area 220, with a lateral offset, may enable the conductive contact pad 224 to be arranged over the sensor area 220 while also enabling the current to be provided down into the IC layer stack 304 (e.g., to the bottom conductive layers). Thus, the conductive contact pad 224 may laterally extend over both the sensor area 220 and the conductive pillar 308.

As indicated above, FIG. 3 is provided as an example. Other examples may differ from what is described with regard to FIG. 3. The number and arrangement of components shown in FIG. 3 are provided as an example. In practice, the chip-scale package 300 may include additional components, fewer components, different components, or differently arranged components than those shown in FIG. 3.

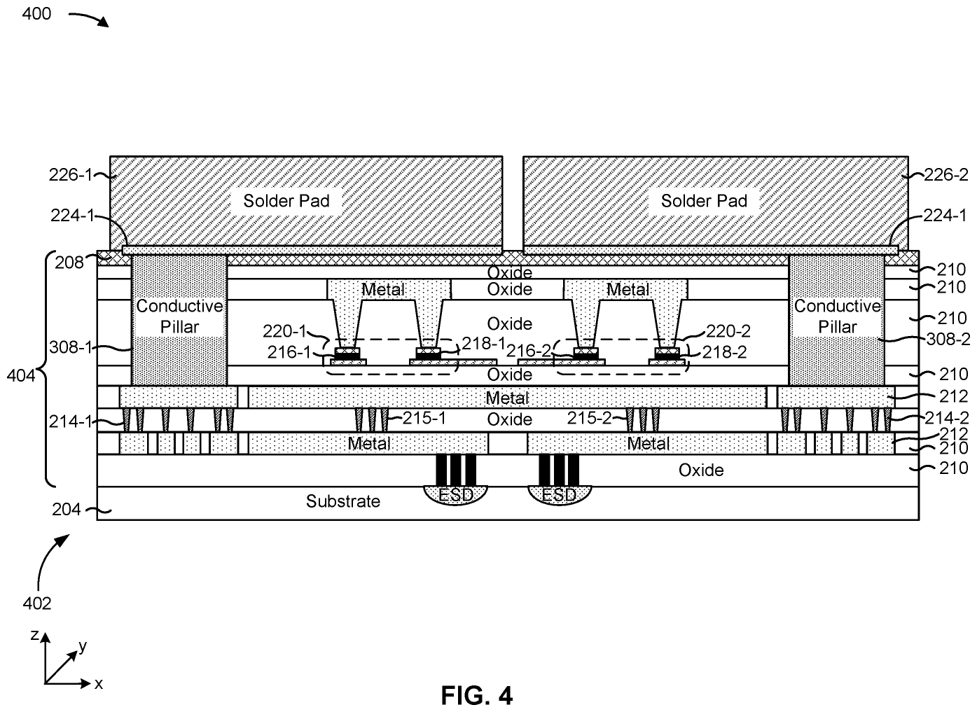

FIG. 4 shows a cross-section of a chip-scale package 400 according to one or more implementations. Some aspects of the chip-scale package 400 may be similar to the chip-scale packages 200 and 300 described in connection with FIGS. 2 and 3. In particular, the chip-scale package 400 may include a magnetic sensor IC 402 that has multiple sensor areas, with each sensor area having a respective plurality of magnetoresistive sensing elements (e.g., TMR sensing elements). In addition, each sensor area may be associated with a respective conductive contact pad, a respective solder pad, and respective electrical connections formed by respective conductive layers and respective conductive vias that conduct current from the respective conductive contact pad to the respective plurality of magnetoresistive sensing elements of the sensor area.

For example, the chip-scale package 400 may include a first plurality of magnetoresistive sensing elements 216-1 and 218-1 arranged in a first sensor area 220-1, and a second plurality of magnetoresistive sensing elements 216-2 and 218-2 arranged in a second sensor area 220-2. The first sensor area 220-1 and the second sensor area 220-2 may be laterally separated, for example, in the x-direction. The first plurality of magnetoresistive sensing elements 216-1 and 218-1 and the second plurality of magnetoresistive sensing elements 216-2 and 218-2 may be integrated in an IC layer stack 404 of the magnetic sensor IC 402. The IC layer stack 404 may include the plurality of isolation layers 210 and the plurality of conductive layers.

In addition, the IC layer stack 404 may include a first plurality of conductive vias 214-1 and a second plurality of conductive vias 215-1 corresponding to a conductive path (e.g., a first current path) for the first plurality of magnetoresistive sensing elements 216-1 and 218-1. Additionally, the IC layer stack 404 may include a third plurality of conductive layers vias 214-2 and a fourth plurality of conductive vias 215-2 corresponding to a conductive path (e.g., a second current path) for the second plurality of magnetoresistive sensing elements 216-2 and 218-2.

The chip-scale package 400 may include a first conductive contact pad 224-1 arranged on or integrated in the IC layer stack 404. In particular, the first conductive contact pad 224-1 may be arranged over the first sensor area 220-1 such that the first conductive contact pad 224-1 and the first sensor area 220-1 (e.g., the first plurality of magnetoresistive sensing elements 216-1 and/or 218-1) at least partially vertically overlap, for example, in the z-direction. Additionally, the chip-scale package 400 may include a second conductive contact pad 224-2 arranged on or integrated in the IC layer stack 404. In particular, the second conductive contact pad 224-2 may be arranged over the second sensor area 220-2 such that the second conductive contact pad 224-2 and the second sensor area 220-2 (e.g., the second plurality of magnetoresistive sensing elements 216-2 and/or 218-2) at least partially vertically overlap, for example, in the z-direction.

The chip-scale package 400 may include a first solder pad 226-1 arranged directly on the first conductive contact pad 224-1, and may include a second solder pad 226-2 arranged directly on the second conductive contact pad 224-2. The first conductive contact pad 224-1 may be arranged vertically between the first solder pad 224-1 and the first sensor area 220-1. The second conductive contact pad 224-2 may be arranged vertically between the second solder pad 224-2 and the second sensor area 220-2.

In addition, the IC layer stack 404 may include a first conductive pillar 308-1 and a second conductive pillar 308-2. The first conductive pillar 308-1 may connect the first conductive pad 224-1 to the first plurality of magnetoresistive sensing elements 216-1 and 218-1 by way of the first plurality of conductive vias 214-1 and the second plurality of conductive vias 214-2. The first conductive pillar 308-1 may be laterally offset from the first plurality of magnetoresistive sensing elements 216-1 and 218-1, for example, in the x-direction. Thus, the first conductive contact pad 224-1 may laterally extend over both the first sensor area 220-1 and the first conductive pillar 308-1.

The second conductive pillar 308-2 may connect the second conductive pad 224-2 to the second plurality of magnetoresistive sensing elements 216-2 and 218-2 by way of the third plurality of conductive vias 214-2 and the fourth plurality of conductive vias 214-2. The second conductive pillar 308-2 may be laterally offset from the second plurality of magnetoresistive sensing elements 216-2 and 218-2, for example, in the x-direction. Thus, the second conductive contact pad 224-2 may laterally extend over both the second sensor area 220-2 and the second conductive pillar 308-2.

By forming the first conductive contact pad 224-1 over the first sensor area 220-1 and by forming the second conductive contact pad 224-2 over the second sensor area 220-2, a total lateral area in an x-y plane of the magnetic sensor IC 402 may be reduced. The chip-scale package 400 may be formed without any wire bonds. Moreover, by forming the first conductive contact pad 224-1 and the second conductive contact pad 224-2 as the uppermost conductive layer of the magnetic sensor IC 402, a manufacturing process of the magnetic sensor IC 402 may be simplified, which may result in reduced manufacturing costs.

As indicated above, FIG. 4 is provided as an example. Other examples may differ from what is described with regard to FIG. 4. The number and arrangement of components shown in FIG. 4 are provided as an example. In practice, the chip-scale package 400 may include additional components, fewer components, different components, or differently arranged components than those shown in FIG. 4. For example, the chip-scale package 400 may include a thick isolation layer similar to the thick isolation layer 306 described in connection with FIG. 3. Thus, features described in connection with one implementation may be incorporated in another implementation, unless explicitly noted otherwise.

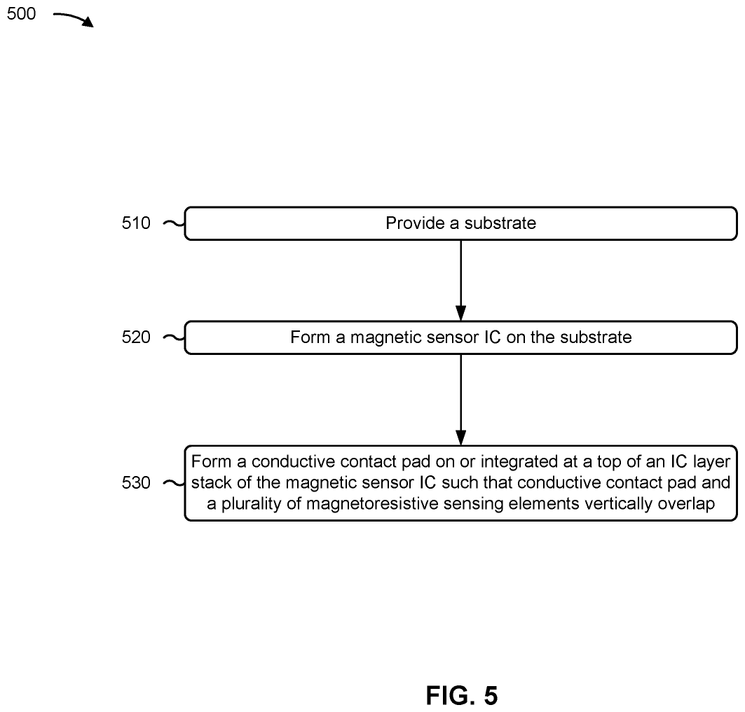

FIG. 5 is a flowchart of an example process 500 associated with forming a pad over active sensor cells integrated in a chip package. For example, the process 500 may be directed to a method of manufacturing a chip-scale package. In some implementations, one or more process blocks of FIG. 5 are performed by a manufacturing equipment configured to produce TMR sensing elements, magnetic sensor ICs, and/or chip-scale packages.

As shown in FIG. 5, process 500 may include providing a substrate (block 510). For example, the substrate 204 may be provide based on semiconductor wafer processes.

As further shown in FIG. 5, process 500 may include forming a magnetic sensor IC on the substrate (block 520). The magnetic sensor IC may include an IC layer stack comprising a plurality of isolation layers and a plurality of conductive layers, and a plurality of magnetoresistive sensing elements integrated in a sensor area of the IC layer stack. For example, the magnetic sensor IC 202, 302, or 402 may be formed on the substrate 204, as described above.

As further shown in FIG. 5, process 500 may include forming a conductive contact pad on or integrated at a top of the IC layer stack (block 530). The conductive contact pad may be arranged over the plurality of magnetoresistive sensing elements such that the conductive contact pad and a sensor area (e.g., the plurality of magnetoresistive sensing elements) at least partially vertically overlap. For example, the conductive contact pad 224 may be formed on or integrated at a top of the IC layer stack of the magnetic sensor IC 202, 302, or 402. The conductive contact pad 224 may be arranged over the magnetoresistive sensing elements 216 and/or 218 such that the conductive contact pad and the magnetoresistive sensing elements 216 and/or 218 vertically overlap, as described above.

Process 500 may include additional implementations, such as any single implementation or any combination of implementations described below and/or in connection with one or more other processes described elsewhere herein.

In a first implementation, the conductive contact pad may be a last metal layer of the IC layer stack.

In a second implementation, the conductive contact pad may be formed after integrating the plurality of magnetoresistive sensing elements in the IC layer stack.

In a third implementation, process 500 may include forming a magnetic metal layer on top of the conductive contact pad such that the magnetic metal layer and the sensor area (e.g., the plurality of magnetoresistive sensing elements) at least partially vertically overlap.

In a fourth implementation, the magnetic metal layer and the plurality of magnetoresistive sensing elements are separated by a vertical distance of at least 25 μm.

In a fifth implementation, forming the magnetic sensor IC may include forming conductive structures configured to electrically couple the plurality of magnetoresistive sensing elements to the conductive contact pad. The conductive structures may extend vertically within the IC layer stack and may be laterally offset from the sensor area.

Although FIG. 5 shows example blocks of process 500, in some implementations, process 500 includes additional blocks, fewer blocks, different blocks, or differently arranged blocks than those depicted in FIG. 5. Additionally, or alternatively, two or more of the blocks of process 500 may be performed in parallel.

The following provides an overview of some Aspects of the present disclosure:

Aspect 1: A chip-scale package, comprising: a magnetic sensor IC comprising: an IC layer stack comprising a plurality of isolation layers and a plurality of conductive layers; and a magnetoresistive sensing element integrated in the IC layer stack, wherein the magnetoresistive sensing element includes a reference layer having a fixed reference magnetization aligned with a magnetization axis, and a magnetic free layer having a magnetically free magnetization, and wherein the magnetically free magnetization is variable in a presence of an external magnetic field; and a conductive contact pad arranged on or integrated in the IC layer stack, wherein the conductive contact pad is arranged over the magnetoresistive sensing element such that the conductive contact pad and the magnetoresistive sensing element at least partially vertically overlap.

Aspect 2: The chip-scale package of Aspect 1, wherein at least one isolation layer of the IC layer stack is arranged vertically between the conductive contact pad and the magnetoresistive sensing element.

Aspect 3: The chip-scale package of Aspect 2, wherein the IC layer stack comprises a conductive pillar coupled to the conductive contact pad and a conductive layer of the plurality of conductive layers, wherein the conductive pillar vertically extends through the at least one isolation layer, between the conductive contact pad and the conductive layer, and wherein the conductive pillar is laterally offset from the magnetoresistive sensing element.

Aspect 4: The chip-scale package of any of Aspects 1-3, further comprising: a solder pad arranged directly on the conductive contact pad, wherein the conductive contact pad is arranged vertically between the solder pad and the magnetoresistive sensing element.

Aspect 5: The chip-scale package of Aspect 4, wherein at least one isolation layer of the IC layer stack is arranged vertically between the conductive contact pad and the magnetoresistive sensing element, and wherein the solder pad and the magnetoresistive sensing element are separated by a vertical distance of at least 25 μm.

Aspect 6: The chip-scale package of Aspect 4, wherein the conductive contact pad is made of at least one of aluminum or copper, and wherein the solder pad is made of a nickel-phosphorus alloy.

Aspect 7: The chip-scale package of Aspect 6, wherein the solder pad is made of a nickel-phosphorus-palladium-gold alloy (NiP/Pd/Au).

Aspect 8: The chip-scale package of any of Aspects 1-7, wherein the conductive contact pad is electrically coupled to the magnetoresistive sensing element by one or more conductive layers of the plurality of conductive layers.

Aspect 9: The chip-scale package of Aspect 8, wherein the IC layer stack comprises a plurality of conductive vias that connect the conductive contact pad to the one or more conductive layers, wherein the plurality of conductive vias extend vertically into the IC layer stack, and wherein the plurality of conductive vias are arranged laterally offset from the magnetoresistive sensing element.

Aspect 10: The chip-scale package of Aspect 8, wherein the IC layer stack comprises a conductive pillar that connects the conductive contact pad to the one or more conductive layers, wherein the conductive pillar extends vertically into the IC layer stack from the conductive contact pad, and wherein the conductive pillar is arranged laterally offset from the magnetoresistive sensing element.

Aspect 11: The chip-scale package of Aspect 8, wherein the conductive contact pad is configured to supply a current to the magnetoresistive sensing element.

Aspect 12: The chip-scale package of any of Aspects 1-11, wherein the conductive contact pad is an uppermost conductive layer of the IC layer stack.

Aspect 13: A chip-scale package, comprising: a magnetic sensor IC comprising: an IC layer stack comprising a plurality of isolation layers and a plurality of conductive layers; and a plurality of magnetoresistive sensing elements integrated in the IC layer stack, including a first plurality of magnetoresistive sensing elements arranged in a first sensor area and a second plurality of magnetoresistive sensing elements arranged in a second sensor area, wherein the first sensor area and the second sensor area are laterally separated; a first conductive contact pad arranged on or integrated in the IC layer stack, wherein the first conductive contact pad is arranged over the first sensor area such that the first conductive contact pad and the first sensor area at least partially vertically overlap; and a second conductive contact pad arranged on or integrated in the IC layer stack, wherein the second conductive contact pad is arranged over the second sensor area such that the second conductive contact pad and the second sensor area at least partially vertically overlap.

Aspect 14: The chip-scale package of Aspect 13, wherein the plurality of magnetoresistive sensing elements are TMR sensing elements.

Aspect 15: A method of manufacturing a chip-scale package, comprising: providing a substrate; forming a magnetic sensor IC on the substrate, wherein the magnetic sensor IC includes: an IC layer stack comprising a plurality of isolation layers and a plurality of conductive layers, and a plurality of magnetoresistive sensing elements integrated in a sensor area of the IC layer stack; and forming a conductive contact pad on or integrated at a top of the IC layer stack, wherein the conductive contact pad is arranged over the plurality of magnetoresistive sensing elements such that the conductive contact pad and the plurality of magnetoresistive sensing elements at least partially vertically overlap.

Aspect 16: The method of Aspect 15, wherein the conductive contact pad is a last metal layer of the IC layer stack.

Aspect 17: The method of any of Aspects 15-16, wherein the conductive contact pad is formed after integrating the plurality of magnetoresistive sensing elements in the IC layer stack.

Aspect 18: The method of any of Aspects 15-17, further comprising: forming a magnetic metal layer on top of the conductive contact pad such that the magnetic metal layer and the plurality of magnetoresistive sensing elements at least partially vertically overlap.

Aspect 19: The method of Aspect 18, wherein the magnetic metal layer and the plurality of magnetoresistive sensing elements are separated by a vertical distance of at least 25 μm.

Aspect 20: The method of any of Aspects 15-19, wherein forming the magnetic sensor IC includes forming conductive structures configured to electrically couple the plurality of magnetoresistive sensing elements to the conductive contact pad, and wherein the conductive structures extend vertically within the IC layer stack and are laterally offset from the sensor area.

Aspect 21: A system configured to perform one or more operations recited in one or more of Aspects 1-20.

Aspect 22: An apparatus comprising means for performing one or more operations recited in one or more of Aspects 1-20.

Aspect 23: A non-transitory computer-readable medium storing a set of instructions, the set of instructions comprising one or more instructions that, when executed by a device, cause the device to perform one or more operations recited in one or more of Aspects 15-20.

Aspect 24: A computer program product comprising instructions or code for executing one or more operations recited in one or more of Aspects 15-20.

The foregoing disclosure provides illustration and description, but is not intended to be exhaustive or to limit the implementations to the precise form disclosed. Modifications and variations may be made in light of the above disclosure or may be acquired from practice of the implementations.

Some implementations may be described herein in connection with thresholds. As used herein, “satisfying” a threshold may refer to a value being greater than the threshold, more than the threshold, higher than the threshold, greater than or equal to the threshold, less than the threshold, fewer than the threshold, lower than the threshold, less than or equal to the threshold, equal to the threshold, or the like.

As used herein, the term “component” is intended to be broadly construed as hardware, firmware, or a combination of hardware and software. Systems and/or methods described herein may be implemented in different forms of hardware, firmware, or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be designed to implement the systems and/or methods based on the description herein.

Any of the processing components may be implemented as a central processing unit (CPU) or other processor reading and executing a software program from a non-transitory computer-readable recording medium such as a hard disk or a semiconductor memory device. For example, instructions may be executed by one or more processors, such as one or more CPUs, digital signal processors (DSPs), general-purpose microprocessors, application-specific integrated circuits (ASICs), field programmable logic arrays (FPLAs), programmable logic controller (PLC), or other equivalent integrated or discrete logic circuitry. Accordingly, the term “processor,” as used herein, refers to any of the foregoing structures or any other structure suitable for implementation of the techniques described herein. Software may be stored on a non-transitory computer-readable medium such that the non-transitory computer readable medium includes program code or a program algorithm stored thereon that, when executed, causes the processor, via a computer program, to perform the steps of a method.

A controller including hardware may also perform one or more of the techniques of this disclosure. A controller, including one or more processors, may use electrical signals and digital algorithms to perform its receptive, analytic, and control functions, which may further include corrective functions. Such hardware, software, and firmware may be implemented within the same device or within separate devices to support the various techniques described in this disclosure.

A signal processing circuit and/or a signal conditioning circuit may receive one or more signals (e.g., measurement signals) from one or more components in the form of raw measurement data and may derive, from the measurement signal, further information. “Signal conditioning,” as used herein, refers to manipulating an analog signal in such a way that the signal meets the requirements of a next stage for further processing. Signal conditioning may include converting from analog to digital (e.g., via an analog-to-digital converter), amplification, filtering, converting, biasing, range matching, isolation, and any other processes required to make a signal suitable for processing after conditioning.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a and b, a and c, b and c, and a, b, and c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

Further, it is to be understood that the disclosure of multiple acts or functions disclosed in the specification or in the claims may not be construed as to be within the specific order. Therefore, the disclosure of multiple acts or functions will not limit these to a particular order unless such acts or functions are not interchangeable for technical reasons. Furthermore, in some implementations, a single act may include or may be broken into multiple sub acts. Such sub acts may be included and part of the disclosure of this single act unless explicitly excluded.

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.”

Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A chip-scale package, comprising:
a magnetic sensor integrated circuit (IC) comprising:
an IC layer stack comprising a plurality of isolation layers and a plurality of conductive layers; and
a magnetoresistive sensing element integrated in the IC layer stack, wherein the magnetoresistive sensing element includes a reference layer having a fixed reference magnetization aligned with a magnetization axis, and a magnetic free layer having a magnetically free magnetization, and wherein the magnetically free magnetization is variable in a presence of an external magnetic field; and
a conductive contact pad arranged on or integrated in the IC layer stack, wherein the conductive contact pad is arranged over the magnetoresistive sensing element such that the conductive contact pad and the magnetoresistive sensing element at least partially vertically overlap.

2. The chip-scale package of claim 1, wherein at least one isolation layer of the IC layer stack is arranged vertically between the conductive contact pad and the magnetoresistive sensing element.

3. The chip-scale package of claim 2, wherein the IC layer stack comprises a conductive pillar coupled to the conductive contact pad and a conductive layer of the plurality of conductive layers,
wherein the conductive pillar vertically extends through the at least one isolation layer, between the conductive contact pad and the conductive layer, and
wherein the conductive pillar is laterally offset from the magnetoresistive sensing element.

4. The chip-scale package of claim 1, further comprising:
a solder pad arranged directly on the conductive contact pad,
wherein the conductive contact pad is arranged vertically between the solder pad and the magnetoresistive sensing element.

5. The chip-scale package of claim 4, wherein at least one isolation layer of the IC layer stack is arranged vertically between the conductive contact pad and the magnetoresistive sensing element, and
wherein the solder pad and the magnetoresistive sensing element are separated by a vertical distance of at least 25 μm.

6. The chip-scale package of claim 4, wherein the conductive contact pad is made of at least one of aluminum or copper, and
wherein the solder pad is made of a nickel-phosphorus alloy.

7. The chip-scale package of claim 6, wherein the solder pad is made of a nickel-phosphorus-palladium-gold alloy (NiP/Pd/Au).

8. The chip-scale package of claim 1, wherein the conductive contact pad is electrically coupled to the magnetoresistive sensing element by one or more conductive layers of the plurality of conductive layers.

9. The chip-scale package of claim 8, wherein the IC layer stack comprises a plurality of conductive vias that connect the conductive contact pad to the one or more conductive layers,
wherein the plurality of conductive vias extend vertically into the IC layer stack, and
wherein the plurality of conductive vias are arranged laterally offset from the magnetoresistive sensing element.

10. The chip-scale package of claim 8, wherein the IC layer stack comprises a conductive pillar that connects the conductive contact pad to the one or more conductive layers,
wherein the conductive pillar extends vertically into the IC layer stack from the conductive contact pad, and
wherein the conductive pillar is arranged laterally offset from the magnetoresistive sensing element.

11. The chip-scale package of claim 8, wherein the conductive contact pad is configured to supply a current to the magnetoresistive sensing element.

12. The chip-scale package of claim 1, wherein the conductive contact pad is an uppermost conductive layer of the IC layer stack.

13. A chip-scale package, comprising:
a magnetic sensor integrated circuit (IC) comprising:
an IC layer stack comprising a plurality of isolation layers and a plurality of conductive layers; and
a plurality of magnetoresistive sensing elements integrated in the IC layer stack, including a first plurality of magnetoresistive sensing elements arranged in a first sensor area and a second plurality of magnetoresistive sensing elements arranged in a second sensor area, wherein the first sensor area and the second sensor area are laterally separated;
a first conductive contact pad arranged on or integrated in the IC layer stack, wherein the first conductive contact pad is arranged over the first sensor area such that the first conductive contact pad and the first sensor area at least partially vertically overlap; and
a second conductive contact pad arranged on or integrated in the IC layer stack, wherein the second conductive contact pad is arranged over the second sensor area such that the second conductive contact pad and the second sensor area at least partially vertically overlap.

14. The chip-scale package of claim 13, wherein the plurality of magnetoresistive sensing elements are tunnel magnetoresistive (TMR) sensing elements.

15. A method of manufacturing a chip-scale package, comprising:
providing a substrate;
forming a magnetic sensor integrated circuit (IC) on the substrate, wherein the magnetic sensor IC includes:
an IC layer stack comprising a plurality of isolation layers and a plurality of conductive layers, and
a plurality of magnetoresistive sensing elements integrated in a sensor area of the IC layer stack; and
forming a conductive contact pad on or integrated at a top of the IC layer stack, wherein the conductive contact pad is arranged over the plurality of magnetoresistive sensing elements such that the conductive contact pad and the plurality of magnetoresistive sensing elements at least partially vertically overlap.

16. The method of claim 15, wherein the conductive contact pad is a last metal layer of the IC layer stack.

17. The method of claim 15, wherein the conductive contact pad is formed after integrating the plurality of magnetoresistive sensing elements in the IC layer stack.

18. The method of claim 15, further comprising:
forming a magnetic metal layer on top of the conductive contact pad such that the magnetic metal layer and the plurality of magnetoresistive sensing elements at least partially vertically overlap.

19. The method of claim 18, wherein the magnetic metal layer and the plurality of magnetoresistive sensing elements are separated by a vertical distance of at least 25 μm.

20. The method of claim 15, wherein forming the magnetic sensor IC includes forming conductive structures configured to electrically couple the plurality of magnetoresistive sensing elements to the conductive contact pad, and
wherein the conductive structures extend vertically within the IC layer stack and are laterally offset from the sensor area.
